(19) United States
(12) Patent Application Publication
(10) Pub. No.: US 2023/0011953 A1
(43) Pub. Date: Jan. 12, 2023

(54) IMAGE SENSOR FOR CORRECTING THE ELECTRONIC NOISE OF A SENSOR

(71) Applicant: ISORG, Limoges CEDEX 3 (FR)

(72) Inventors: Benjamin BOUTHINON, GRENOBLE (FR); Pierre MULLER, GRENOBLE (FR); Noémie BALLOT, GRENOBLE (FR)

(21) Appl. No.: 17/783,835

(22) PCT Filed: Dec. 9, 2020
(86) PCT No.: PCT/EP2020/085381

§ 371 Date: Jun. 9, 2022

(30) Foreign Application Priority Data
Dec. 11, 2019 (FR) 1914199

(51) Int. Cl. H01L 27/146

(52) U.S. Cl. CPC H01L 27/14605; H01L 27/14665

(57) ABSTRACT

An image sensor includes first pixels and second pixels. The second pixels of the image sensor are distinct from the first pixels of the image sensor.

### RELATED APPLICATIONS

The present patent application claims the priority benefit of French patent application FR19/14199 which is herein incorporated by reference.

### FIELD

The present disclosure concerns an image acquisition system.

### BACKGROUND

An image acquisition system generally comprises an image sensor and an optical system, interposed between the sensitive portion of the image sensor and the object to be imaged and which enables to form a sharp image of the object to be imaged on the sensitive portion of the image sensor.

The image sensor generally comprises an array of photodetectors capable of generating a signal proportional to the received light intensity.

### SUMMARY OF THE INVENTION

There is a need to improve image acquisition systems.

An embodiment overcomes all or part of the disadvantages of image acquisition systems.

An embodiment provides an image sensor comprising first pixels and second pixels distinct from the first pixels wherein the first and the second pixels comprise a first electrode, an active layer, and a second electrode electrically coupled to a conductive track, the first electrode of the second pixels being dissociated from the first electrode of the first pixels.

An embodiment provides an image sensor comprising first pixels and second pixels distinct from the first pixels, wherein the first pixels comprise a first electrode, an active layer, and a second electrode electrically coupled to a conductive track, the second pixels comprising at least no first electrode.

An embodiment provides an image sensor comprising first pixels and second pixels distinct from the first pixels.

According to an embodiment, each second pixel is formed of one or a plurality of elements selected, in a smaller number, among elements constitutive of the first pixels.

According to an embodiment, each second pixel comprises an electrically-insulating area between a first electrode and a second electrode.

According to an embodiment, a first electrode of the second pixels is dissociated from a first electrode of the first pixels.

According to an embodiment, the first pixels comprise the following elements:
a first electrode;
an active layer;
a second electrode; and
a conductive via coupling the second electrode to a conductive track.

According to an embodiment, each second pixel comprises the same elements as the first pixels.

According to an embodiment, the insulating area is located between the first electrode and the active layer.

According to an embodiment, the insulating layer is located between the second electrode and the active layer.

According to an embodiment, the second pixels comprise no first electrode.

According to an embodiment, the second pixels comprise no active layer.

According to an embodiment, the second pixels comprise no conductive via.

According to an embodiment, the first pixels and the second pixels are juxtaposed and organized in rows and in columns.

According to an embodiment, the second pixels are organized in columns which are adjacent and located on one of the edges of the sensor or distributed on two edges of the sensor.

An embodiment of provides an image sensor manufacturing method, comprising the following steps:
forming the second electrode on a surface of a stack;
forming the active layer on the lower electrodes, on the side of said surface; and
forming the first electrode on the active layer, on the side of said surface,
to form the first pixels.

According to an embodiment, the method further comprises a step of removal of all or part of the first electrode, or of the first electrode and of the active layer, to form the second pixels.

According to an embodiment, the forming of the second pixels only comprises part of said steps, to obtain a sensor.

According to an embodiment, the method further comprises a step of deposition of the insulating layer, to form the second pixels.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 illustrates, in a partial simplified cross-section view, an embodiment of an image acquisition system;

FIG. 2 illustrates, in a partial simplified top view, an embodiment of an image sensor;

FIG. 3 illustrates, in a partial simplified top view, another embodiment of an image sensor;

FIG. 4 partial and schematically shows a usual pixel of an image sensor and its readout circuit;

FIG. 5 illustrates, in a partial simplified cross-section view, an example of a pixel of a usual image sensor;

FIG. 6 illustrates, in partial simplified respective top and cross-section views (A) and (B), an example of an image sensor;

FIG. 7 illustrates, in a partial simplified cross-section view, an embodiment of a pixel of the image sensor of FIG. 6;

FIG. 8 illustrates, in a partial simplified cross-section view, another embodiment of a pixel of the image sensor of FIG. 6;

FIG. 9 illustrates, in a partial simplified cross-section view, still another embodiment of a pixel of an image sensor;

FIG. 10 illustrates, in a partial simplified cross-section view, still another embodiment of a pixel of an image sensor;

FIG. 11 illustrates, in a partial simplified cross-section view, still another embodiment of a pixel of an image sensor;

FIG. 12 illustrates, in partial simplified respective top and cross-section views (A) and (B), another example of an image sensor; and

FIG. 13 illustrates in a partial simplified cross-section view an embodiment of a pixel of the image sensor of FIG. 12.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the forming of the optical filter and of the other elements than the image sensor has not been detailed, the described embodiments and implementation modes being compatible with the usual forming of the filter and of these other elements.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

In the following description, “visible light” designates an electromagnetic radiation having a wavelength in the range from 400 nm to 700 nm and “infrared radiation” designates an electromagnetic radiation having a wavelength in the range from 700 nm to 1 mm. In infrared radiation, one can particularly distinguish near infrared radiation having a wavelength in the range from 700 nm to 1.7 μm.

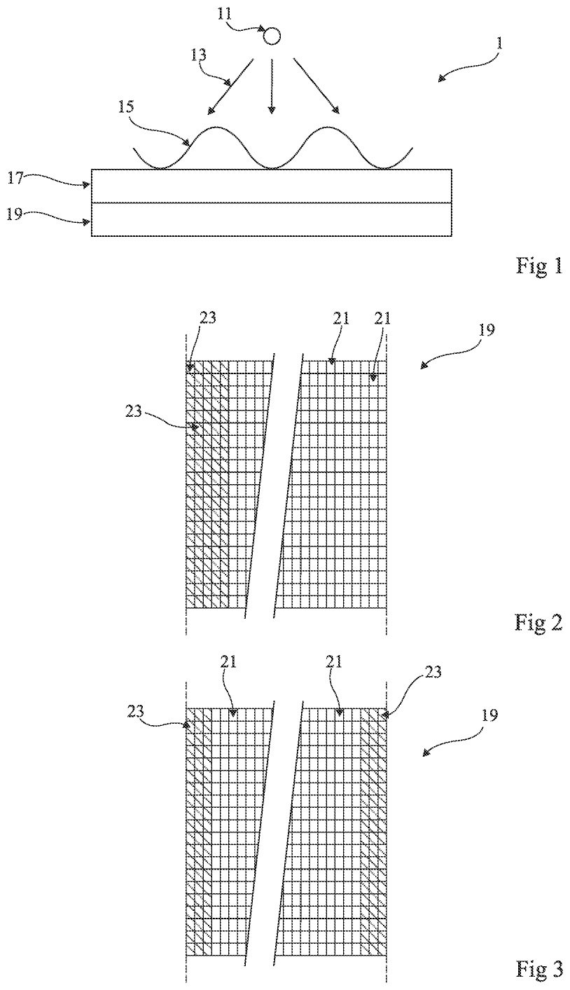

FIG. 1 illustrates in a partial simplified cross-section view an embodiment of an image acquisition system.

Acquisition system 1 comprises from top to bottom:
a light source 11 which emits a radiation 13;
an object 15;
an optical filter 17; and
an image sensor 19, for example, a complementary metal oxide semiconductor or CMOS sensor or a sensor based on thin film transistors (TFT), which may be coupled to inorganic photodiodes (crystalline silicon for a CMOS sensor or amorphous silicon for a TFT sensor) or organic photodiodes.

Image acquisition system 1 further comprises circuits, not shown, for processing the signals supplied by image sensor 19 comprising, for example, a microprocessor.

Light source 11 is illustrated above object 15. It may however, as a variant, be located between object 15 and optical filter 17.

Radiation 13 is for example in the visible range and/or in the infrared range. It may be a radiation of a single wavelength or a radiation of a plurality of wavelengths (or wavelength range).

The photodiodes of image sensor 19 generally form a pixelated array. Each photodiode for example defines a pixel of image sensor 19. Within the array, the photodiodes are for example aligned in rows and in columns.

In the present disclosure, the term “pixel” is used to designate a portion of the structure of image sensor 19 comprising at least one pixel selection transistor and all or part of the elements which form a photodiode.

Some of the pixels of the array are generally used as a reference to only detect and record the noise of sensor 19 and of its electronic system. The noise is then deduced from the signals captured by the other pixels of sensor 19 to correct them.

In the following description, the expression “useful pixel” is used to designate a pixel comprising, among others, a photodiode (two electrodes and an active layer) which delivers a useful signal of the captured image. The expression “reference pixel” is used to designate a pixel, distinct from a useful pixel. More precisely, a reference pixel supplies a signal representative of the noise of sensor 19.

FIG. 2 illustrates in a partial simplified top view an embodiment of an image sensor 19.

More particularly, FIG. 2 illustrates an example of distribution of useful pixels 21 or first pixels and of reference pixels 23 or second pixels within an image sensor 19.

Pixels 21 and 23 are preferably aligned in rows and columns. For an image sensor 1 capable of adapting, for example, on a cell phone having a 6-inch, that is, approximately 15-cm, screen, pixels 21 and 23 are for example organized in approximately 2,500 rows and approximately 1,300 columns for an imager having a 500 dots-per-inch (dpi) resolution, that is, a 50.8-μm pixel pitch. The image resolution may for example vary between 254 dpi (that is, a 100-μm pixel pitch) and 1,000 dpi (that is, a 25-μm pixel pitch).

Pixels 21 and 23 are organized in the array so that at least one reference pixel 23 is present per row. Reference pixels 23 are all aligned in same columns. For example, from approximately 4 columns to approximately 64 columns only comprise reference pixels 23. Preferably, from approximately 16 columns to approximately 32 columns only comprise reference pixels 23.

In the embodiment illustrated in FIG. 2, the columns of reference pixels 23 are all juxtaposed and located on one of the edges of sensor 19 (on the left-hand side of sensor 19 in the orientation of FIG. 2).

FIG. 3 illustrates, in a partial simplified top view, another embodiment of an image sensor 19.

The embodiment illustrated in FIG. 3 is substantially identical to the embodiment illustrated in FIG. 2, with the difference that the reference pixel columns 23 are located on two opposite sides of sensor 19. Preferably, a same number of reference pixel columns 23 is present in each edge of sensor 19.

In the embodiments of FIGS. 2 and 3, the noise is detected by an assembly of photodiodes of reference pixels 23. The electronic noise detected by photodiodes of reference pixels 23 of a same row is averaged. The average noise is then used to correct the useful signals detected by the photodiodes of the useful pixels 21 of the same row.

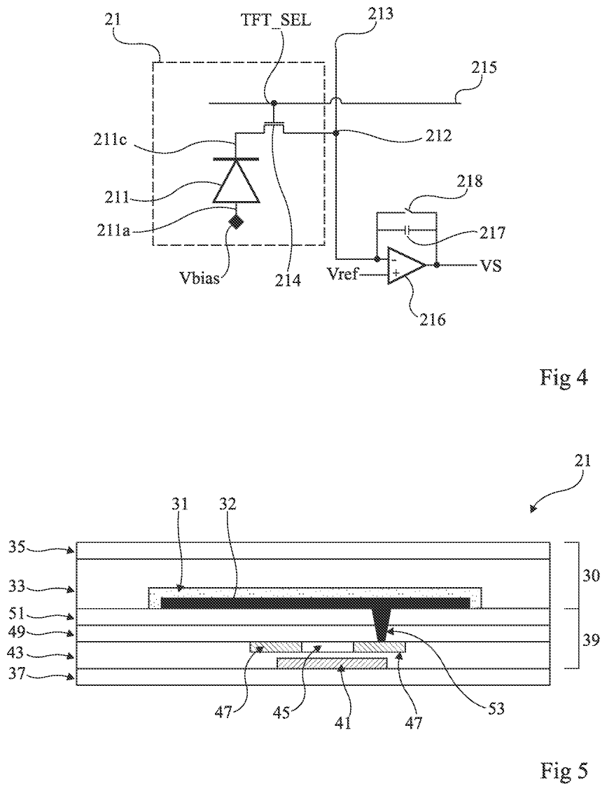

FIG. 4 partially and schematically shows a usual pixel of an image sensor and its readout circuit.

More particularly, FIG. 4 shows an electric diagram showing an example of a useful pixel 21 of an image sensor 19 and its read electronic system.

Each useful pixel 21 comprises a photodiode 211 coupled by its cathode 211c to a node 212 of a conductive track 213 via a metal oxide semiconductor (MOS) transistor 214. Conductive track 213 is generally coupled, preferably connected, to all the transistors 214 of the pixels of a same column.

An anode 211a of photodiode 211 is coupled to a node of application of a bias potential Vbias. The gate of MOS transistor 214 is coupled, preferably connected, to a conductive track 215. Conductive track 215 s generally coupled, preferably connected, to all the gates of the transistors 214 of the pixels 21 of a same row. The gate of MOS transistor 214 is intended to receive a row selection signal TFT_SEL.

The electric diagram illustrated in FIG. 4 comprises, for each column, an operational amplifier 216 having its inverting input (−) coupled to conductive track 213, having its non-inverting input (+) coupled to a source of a reference potential Vref, and having its output delivering a potential VS. The output of amplifier 216 is coupled to its inverting input (−) via a parallel association of a capacitor 217 and of a switch 218.

During an initialization phase, switches 214 and 218 are on to discharge capacitor 217 and photodiode 211. During an integration phase, transistor 214 is off, potential Vbias is set to an inverse bias voltage, and charges are accumulated in photodiode 211 proportionally to the intensity of the received light. In a read phase, transistor 214 is turned on and the charges of photodiode 211 are transferred to the read amplifier (switch 218 being off), more precisely to integration capacitor 217

The noise of the sensor and of its electronic system corresponds to all the noise emitted by tracks 213 and 215 and the readout circuit comprising amplifier 216, capacitor 217, and switch 218.

To detect this noise, the electric circuit of a reference pixel 23 is different from the electric circuit illustrated in FIG. 4 since pixel 23 supplies no signal having a component linked to the exposure to light, so that the main component of the signal is that of noise.

FIG. 5 illustrates in a partial simplified cross-section view an example of a usual image sensor pixel.

More particularly, FIG. 5 shows a useful pixel 21 of an image sensor 19.

In the following description, the upper surface of a structure or of a layer is considered, in the orientation of FIG. 5, as being a front surface and the lower surface of the structure or of the layer, in the orientation of FIG. 5, is considered as being a rear surface.

Each useful pixel 21 comprises a first stack 30 having a photodetector, for example, an organic photodiode also called OPD, formed therein.

Stack 30 comprises the following elements:
a lower electrode 31 (second electrode);
a first active layer 33, in contact with electrode 31, having an active region of the photodiode formed therein; and
an upper electrode (first electrode) 35 in contact with layer 33.

For example, stack 30 further comprises a metal layer 32, under electrode 31. Layer 32 is for example formed of two sub-layers (not shown). A first sub-layer of layer 32 is, for example, made of metal oxide such as indium tin oxide (ITO) enabling to have a desired work function for electrode 31. A second sub-layer of layer 32 forms, for example, a barrier to radiations for the channel 45 of transistor 214 (FIG. 4). The second sub-layer is for example made of a metal, preferably of molybdenum (Mo).

The material of layer 45 may be insensitive to the light to which the image sensor is exposed, stack 30 then comprises no metal layer 32 and electrode 31 is transparent.

Each useful pixel further comprises, under metal layer 32, from bottom to top:
a support or substrate 37 that may have a monolayer or multilayer structure; and
a second stack 39 having the selection transistor (24, FIG. 4) formed therein.

For example, stack 39 comprises:
a first electrically-conductive track 41 resting on support 37, track 41 forming the gate conductor of the transistor;
a second layer 43 of a dielectric material covering support 37 and track 41, forming, among others, the gate insulator of the transistor (214, FIG. 4);
an active region 45;
two second electrically-conductive tracks 47 extending at the surface of dielectric layer 43 forming the drain and source contacts of the transistor with active region 45.
One of tracks 47 is coupled to lower electrode 31 via a conductive contacting via 53. The other one of tracks 47 is electrically coupled to track 213 (FIG. 4), for example, via an electrically-conductive via (not shown);
a third layer 49 of a dielectric material; and
a fourth layer 51 of a resin covering layer 49, electrode 31 resting on layer 51.

Lower electrode 31 corresponds to an electron injecting layer (EIL). Upper electrode 35 corresponds to a hole injecting layer (HIL). The work function of electrodes 31 and 35 is adapted to blocking, collecting, or injecting holes and/or electrons according to whether the interface layer plays the role of a cathode 31 or of an anode 35. More precisely, when the interface layer plays the role of an anode, it corresponds to a hole injecting and electron blocking layer. When the interface layer plays the role of a cathode, it corresponds to an electron injection and hole blocking layer.

Cathode 31 is for example made of a material of a first n conductivity type. Anode 35 is for example made of a material of a second p conductivity type, different from the first conductivity type. The anode is for example made of a mixture of poly(3,4-ethylenedioxythiophene) and of sodium poly(styrene sulfonate) (PEDOT:PSS).

Substrate 37 may be a rigid substrate or a flexible substrate. Substrate 37 may have a monolayer structure or correspond to a stack of at least two layers. An example of a rigid substrate comprises a silicon, germanium, or glass substrate. Preferably, substrate 37 is a flexible film. An example of flexible film comprises a film made of PEN (polyethylene naphthalate), PET (polyethylene terephthalate), PI (polyimide), TAC (cellulose triacetate), COP (cycloolefin copolymer), or PEEK (polyetheretherketone), or a combination of these films such as a PI film protected with a PET film on its back side. Substrate 37 may comprise an inorganic layer, for example, made of glass, covered with an organic layer, for example, made of PEN, PET, PI, TAC, COP. The thickness of substrate 37 may be in the range from 5 μm to 1,500 μm. According to an embodiment, substrate 37 may have a thickness from 10 μm to 500 μm, preferably from 20 μm to 300 μm, particularly in the order of 75 μm, and may have a flexible behavior, that is, substrate 37 may, under the action of an external force, deform, and particularly bend, without breaking or tearing.

Conductive tracks 41 and 47 may comprise or be made of a metallic material, for example, silver (Ag), aluminum (Al), gold (Au), copper (Cu), nickel (Ni), titanium (Ti), chromium (Cr), and molybdenum (Mo). Conductive tracks 41 and 47 may have a monolayer or multilayer structure.

Each insulating layer 43, 49, and 51 of stack 39 may be made of an inorganic material, for example, of silicon oxide (SiO₂) or of silicon nitride (SiN), or may be an insulating organic layer, for example, made of organic resin.

The layer 33 having the photodiodes formed therein may comprise small molecules, oligomers, or polymers. These may be organic or inorganic materials. Layer 33 may comprise an ambipolar semiconductor material, or a mixture of an n-type semiconductor material and of a p-type semiconductor material, for example in the form of stacked layers or of an intimate mixture at a nanometer scale to form a bulk heterojunction. The thickness of layer 33 may be in the range from 50 nm to 2 μm, for example, in the order of 500 nm.

Example of p-type semiconductor polymers capable of forming layer 33 are poly(3-hexylthiophene) (P3HT), poly[N-9′-heptadecanyl-2,7-carbazole-alt-5,5-(4,7-di-2-thienyl-2′,1′,3′-benzothiadiazole)] (PCDTBT), poly[(4,8-bis-(2-ethylhexyloxy)-benzo[1,2-b;4,5-b′] dithiophene)-2,6-diyl-alt-(4-(2-ethylhexanoyl)-thieno[3,4-b] thiophene))-2,6-diyl] (PBDTTT-C), poly[2-methoxy-5-(2-ethyl-hexyloxy)-1,4-phenylene-vinylene] (MEH-PPV), or poly[2,6-(4,4-bis-(2-ethylhexyl)-4H-cyclopenta [2,1-b;3,4-b′]dithiophene)-alt-4,7(2,1,3-benzothiadiazole)] (PCPDTBT).

Examples of n-type semiconductor materials capable of forming layer 33 are fullerenes, particularly C60, [6,6]-phenyl-C₆₁-methyl butanoate ([60]PCBM), [6,6]-phenyl-C₇₁-methyl butanoate ([70]PCBM), perylene diimide, zinc oxide (ZnO), or nanocrystals enabling to form quantum dots.

Active region 45 may be made of polysilicon, particularly low-temperature polycrystalline silicon (LTPS), of amorphous silicon (aSi), of zinc-gallium-indium oxide (IGZO), of polymer, or comprise small molecules used in known fashion for the forming of organic thin film transistors (OTFT).

The method of manufacturing, at the scale of an image sensor 19, useful pixels 21 for example comprises the following successive steps:
forming of second electrodes 31 (cathodes) at the surface of stack 39 and forming of the vias 53 coupling electrodes 31 and some of tracks 47 through layer 51 and layer 49;
deposition of first active layer 33 at the surface of electrodes 31 and at the surface of layer 51; and
deposition of first electrode 35 (anode) at the surface of layer 33.

Electrodes 31 may, according to the embodiment illustrated in FIG. 5, be local. A pixel 21 thus comprises an electrode 31 which is locally deposited.

All pixels 21 may share a same electrode 31 which is then deposited full wafer. The rest of the disclosure takes as an example a structure where electrodes 31 are local. The described embodiments however easily adapt to a structure where all the pixels 21 and 23 share the same electrode 31. The materials forming electrode 31 are then selected to have a laterally negligible conductivity to avoid short-circuits between pixels 21. Electrode 31 is, for example, made of zinc oxide (ZnO), of polyethyelene imine (PEI), or of polyethylenimine ethoxylated (PEIE).

The method of manufacturing useful pixels 21 further comprises the manufacturing of stack 39 comprising, for example, the following successive steps:
forming of first tracks 41 on substrate 37;
deposition of second layer 43, where are formed, in trenches, second tracks 47 and active areas 45;
deposition of third layer 49, at the surface of layer 43, of area 45, and of tracks 47; and
deposition of fourth layer 51 at the surface of layer 49.

According to the considered materials, the method of forming at least certain layers of pixel 21 may correspond to a so-called additive process, for example, by direct printing of the material forming the organic layers at the desired locations, particularly in sol-gel form, for example, by inkjet printing, photogravure, silk-screening, flexography, spray coating, or drop casting. According to the considered materials, the method of forming the layers of pixel 21 may correspond to a so-called subtractive method, where the material forming the organic layers is deposited all over the structure (full wafer) and where the non-used portions are then removed, for example, by photolithography or laser ablation. Methods such as spin coating, spray coating, heliography, slot-die coating, blade coating, flexography, or silk-screening, may in particular be used. When the layers are metallic, the metal is for example deposited by evaporation or by cathode sputtering over the entire support and the metal layers are delimited by etching.

Advantageously, at least some of the layers of pixel 21 may be formed by printing techniques. The materials of the previously-described layers may be deposited in liquid form, for example, in the form of conductive and semiconductor inks by means of inkjet printers. “Materials in liquid form” here also designates gel materials capable of being deposited by printing techniques. Anneal steps may be provided between the depositions of the different layers, but it may occur for the anneal temperatures not to exceed 150° C., and the deposition and the possible anneals may be carried out at the atmospheric pressure.

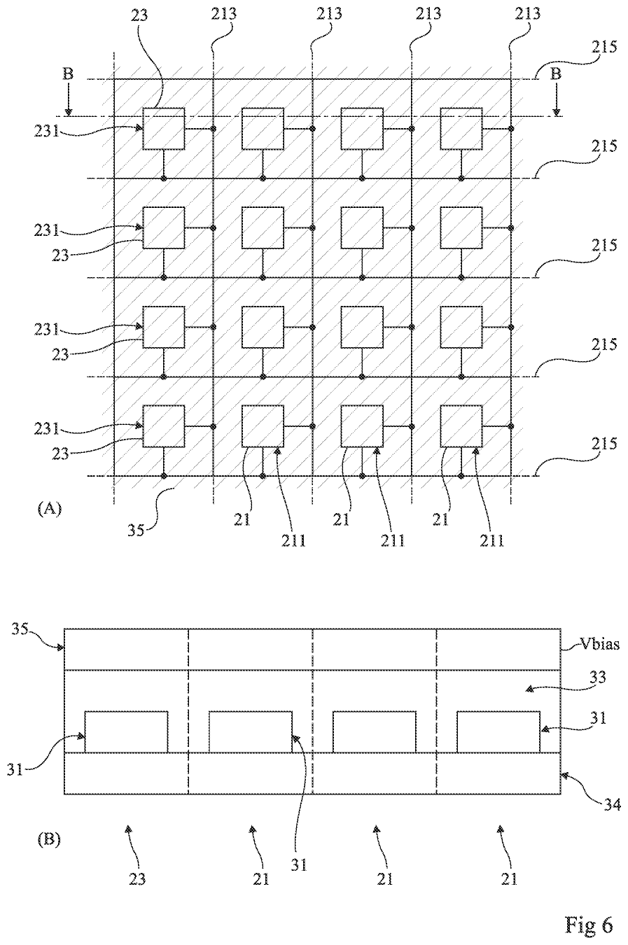

FIG. 6 illustrates, in partial simplified respective top and cross-section views (A) and (B), an example of an image sensor.

More particularly, view (A) of FIG. 6 shows an example of architecture of an image sensor and view (B) of FIG. 6 is a simplified view according to the cross-section plane BB of view (A).

FIG. 6 shows a diagram comprising useful pixels 21 and reference pixels 23. Reference pixels 23 in the example of FIG. 6 comprise an anode (hatched in view (A)) deposited full wafer, an active layer 33 (view (B)), and a cathode 31 forming photodiodes 231 of reference pixels 23.

The photodiodes 211, 231 of a same row are coupled, by their cathodes 31 and row conductor 215, to the readout circuit (FIG. 4). Each column conductor 213 couples the gates of the transistors of the pixels 21 and 23 of a same column.

In the example shown in FIG. 6, view (B), each pixel 21, 23 comprises a cathode 31 (having a surface area substantially equal to the surface area of the photodiode with which it is associated). Cathode 31 for example rest on a stack 34 comprising substrate 37 (FIG. 5) and stack 39 (FIG. 5).

All pixels 21 and 23 share a same anode 35, so that all photodiodes 211 and 213 are biased by anode 35 with the same potential Vbias.

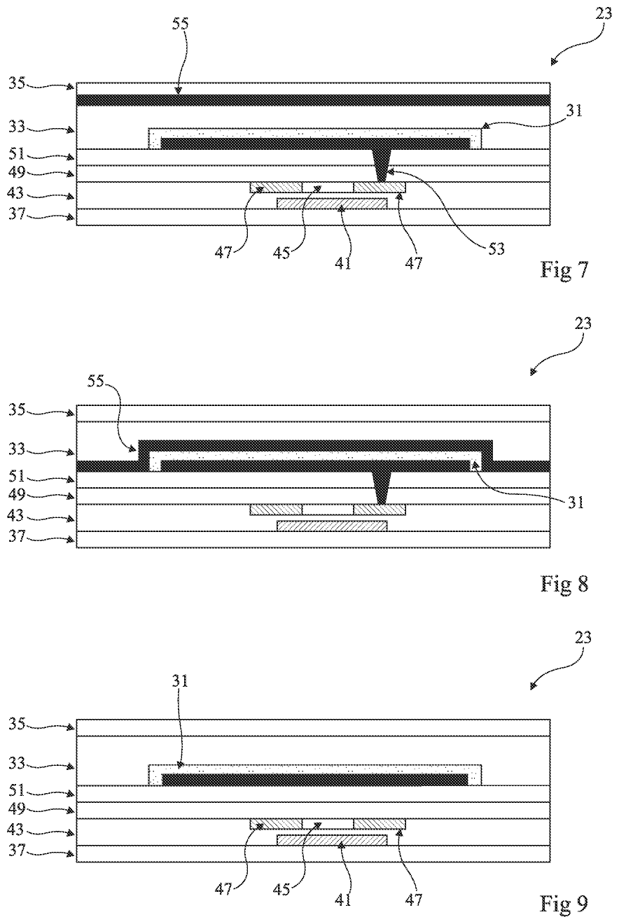

FIG. 7 illustrates in a partial simplified cross-section view an embodiment of a pixel of the image sensor of FIG. 6.

More particularly, FIG. 7 shows a reference pixel 23 substantially identical to the useful pixel 21 shown in FIG. 5, with the difference that it comprises a fifth layer or area 55 between layer 33 and anode 35. The pixel 23 illustrated in FIG. 7 may be integrated in an image sensor 19 as shown in FIG. 6.

Layer 55 is electrically insulating. Layer 55 is for example made of an inorganic material, for example, of silicon oxide or of silicon nitride, or an insulating organic layer, for example, made of organic resin.

According to the embodiment illustrated in FIG. 7, layer 55 is for example deposited over the entire surface of pixels 23. The thickness of layer 55 is for example in the range from 10 nm to 10 μm, preferably in the range from 10 nm to 500 nm.

As a variant, layer 55 is locally deposited and is divided into portions of layer 55. The portions of layer 55 are located opposite the cathodes 31 of reference pixels 23 so that each portion of layer 55 is associated with a single pixel 23. Each portion of layer 55 is vertically aligned with a pixel 23 and has a surface area substantially equal to the surface area of the cathode 31 of said pixel 23.

According to an implementation mode, the method of forming the pixel 23 illustrated in FIG. 7 comprises all the steps of the method of forming pixel 21 illustrated in FIG. 5. The method of forming pixel 23 illustrated in FIG. 7 further comprises an additional step of full wafer deposition of layer 55, for example, by spin coating or by centrifugation, and of photolithography (and an etch step if need be) to locally remove layer 55 in front of useful pixels 21. Layer 55 is only kept in front of reference pixels 23. This additional step is carried out prior to the deposition of electrode 35.

Layer 55 may as a variant be locally deposited in front of pixels 23, for example, by silk-screening, by inkjet, or by a vapor deposition method.

The pixel illustrated in FIG. 7 is a reference pixel 23 since the photodiode (231, FIG. 6) is not biased due to the absence of an electric field in active layer 33.

FIG. 8 illustrates in a partial simplified cross-section view another embodiment of a pixel of the image sensor of FIG. 6.

More particularly, FIG. 8 shows a reference pixel 23 substantially identical to the reference pixel 23 shown in FIG. 7, with the difference that third layer 55 is located between lower electrode 31 and layer 33.

Layer 55 covers the upper surface of each electrode 31 of pixels 23 and, possibly, lateral edges of electrodes 31 and the layer 51 between electrodes 31.

The alternative embodiment mentioning, in FIG. 7, the division of layer 55 into portions of layer 55 may also apply to the embodiment illustrated in FIG. 8.

The pixel illustrated in FIG. 8 is a reference pixel 23 since the photodiode generates no electric bias field.

FIG. 9 illustrates, in a partial simplified cross-section view, another embodiment of a pixel of an image sensor.

More particularly, FIG. 9 shows a reference pixel 23 substantially identical to the useful pixel 21 shown in FIG. 5, with the difference that lower electrode 31 is coupled to no track 47 by the via (53, FIG. 5).

In the absence of a via, photodiode 231 (FIG. 6) is in open circuit. Active layer 33 generates charges which recombine in active layer 33 and are thus not collected by the readout circuit.

The pixel 23 illustrated in FIG. 9 is a reference pixel since, as compared with a pixel 21 such as illustrated in FIG. 4, the link between transistor 214 and photodiode 211 is cut. The photodiode thus delivers no signal to the readout circuit.

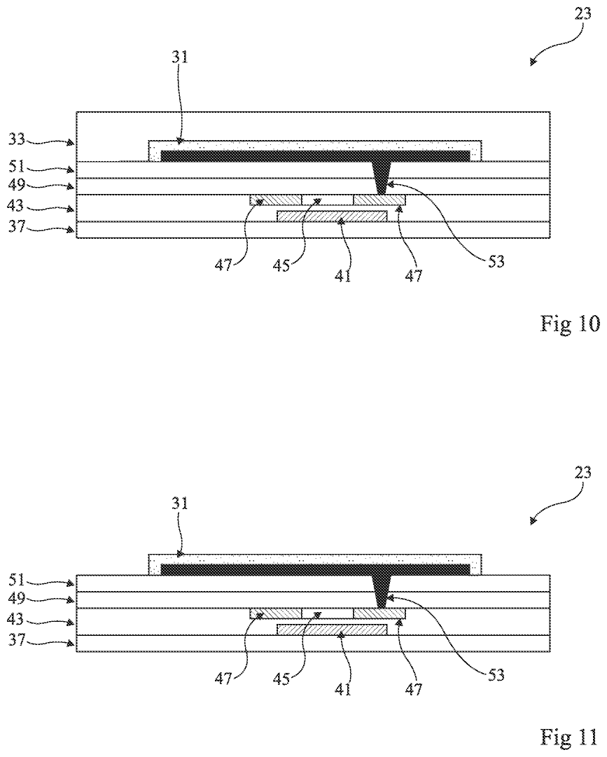

FIG. 10 illustrates, in a partial simplified cross-section view, another embodiment of a pixel of an image sensor.

More particularly, FIG. 10 shows a reference pixel 23 substantially identical to the useful pixel 21 shown in FIG. 5, with the difference that it comprises no upper electrode or anode 35.

According to an implementation mode, the method of forming pixel 23 illustrated in FIG. 10 comprises all the steps of the method of forming the pixel 21 illustrated in FIG. 5 and an additional step of local removal of electrode 35 (FIG. 5). Preferably, electrode 35 is etched in front of electrode 31 across a surface area greater than or equal to the surface area of said electrode 31. Electrode 35 is for example locally etched by a photolithography method. At the scale of image sensor 19, where useful pixels 21 and reference pixels 23 are juxtaposed, electrode 35 is locally removed, at the location of the photodiodes of reference pixels 23.

According to another implementation mode, the method of forming pixel 23 illustrated in FIG. 10 comprises part of the steps of the method of forming pixel 21. Thus, the method of forming pixel 23 does not comprise the step of deposition of electrode 35. At the scale of image sensor 19, where useful pixels 21 and reference pixels 23 are juxtaposed, electrode 35 is locally deposited at the location of useful pixels 21.

The pixel illustrated in FIG. 10 is a reference pixel 23 since it comprises no active photodiode.

FIG. 11 illustrates, in a partial simplified cross-section view, another embodiment of a pixel of an image sensor.

More particularly, FIG. 11 shows a reference pixel 23 substantially identical to the useful pixel 21 shown in FIG. 5, with the difference that it comprises no upper electrode 35 and no active layer 33.

According to an implementation mode, the method of forming the pixel 23 illustrated in FIG. 11 comprises all the steps of the method of forming pixel 21 and an additional step of local removal of electrode 35 and of layer 33. Preferably, electrode 35 and layer 33 are etched in front of electrode 31 across a surface area greater than or equal to the surface area of said electrode 31. Electrode and layer 33 are for example locally etched by a photolithography method. At the scale of image sensor 19, where useful pixels 21 and reference pixels 23 are juxtaposed, electrode 35 and layer 33 are locally removed, at the location of the photodiodes of reference pixels 23.

According to another implementation mode, the method of forming pixel 23 illustrated in FIG. 11 comprises part of the steps of the method of forming the pixel 21 illustrated in FIG. 5. The method of forming pixel 23 comprises neither the step of deposition of electrode 35, nor the step of deposition of layer 33. At the scale of image sensor 19, where useful pixels 21 and reference pixels 23 are juxtaposed, electrode 35 and layer 33 are locally deposited at the locations of useful pixels 21.

The pixel illustrated in FIG. 11 is a reference pixel 23 since it comprises no active photodiode.

In the embodiments illustrated in FIGS. 9 to 11, reference pixels 23 are thus formed of one or a plurality of selected elements, in a smaller number among the elements forming usual pixels 21. In other words, pixels 23 comprise a first electrode 35 (lower electrode) and/or an active layer 45 and/or a second electrode 31 (upper electrode) and/or a conductive via 53.

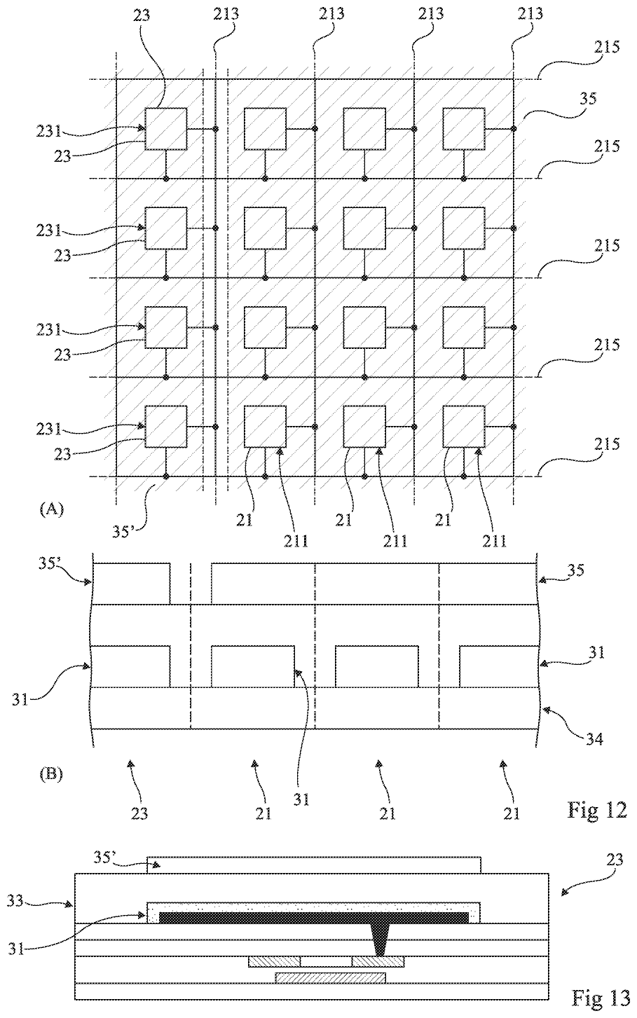

FIG. 12 illustrates, in partial simplified respective top and cross-section views (A) and (B), another example of an image sensor.

More particularly, the view (A) of FIG. 12 shows an example of architecture of an image sensor and view (B) of FIG. 12 is a simplified view according to the cross-section plane BB of view (A).

The architecture of the sensor illustrated in FIG. 12 differs from architecture of the sensor illustrated in FIG. 6 in that the anode 35 of photodiodes 211 and 213 is not common to pixels 21 and 23. Indeed, a first anode 35 is common for all the useful pixels 21 and a second anode 35′, dissociated from anode 35, is common to reference pixels 23. First anode 35 and second anode 35′ are structurally identical but are not coupled.

Thus, given that anodes 35 and 35′ are electrically separated, the bias potential Vbias, applied to anode 35, may not be applied to anode 35′. The anode of photodiodes 231 is then floating. Photodiodes 231 are then in open circuit and integrate no charges.

FIG. 13 illustrates in a partial simplified cross-section view an embodiment of a pixel of the image sensor of FIG. 12.

More particularly, FIG. 13 shows a reference pixel 23 substantially identical to the useful pixel 21 shown in FIG. 5, with the difference that upper electrode 35′ is not coupled to the upper electrode 35 of the neighboring pixel, preferably of the neighboring useful pixel 21. The pixel 23 illustrated in FIG. 13 may be integrated in an image sensor 19 as shown in FIG. 12.

The method of forming pixel 23 illustrated in FIG. 13 comprises all the steps of the method of forming pixel 21 illustrated in FIG. 5 and an additional step of removal of a portion of upper electrode 35 from the edges thereof.

An advantage of the described embodiments is that they enable to correct the noise induced by the image sensor and its electronic system.

Another advantage of the described embodiment is that the formed image sensors are compatible with usual optical filters.

Various embodiments and variants have been described. Those skilled in the art will understand that certain features of these various embodiments and variants may be combined, and other variants will occur to those skilled in the art. In particular, within a same sensor may be combined reference pixels formed according to the different illustrated embodiments. The described embodiments are for example not limited to the examples of dimensions and of materials mentioned hereabove.

Finally, the practical implementation of the embodiments and variants described herein is within the capabilities of those skilled in the art based on the functional indications provided hereinabove.

1. (canceled)

2. An image sensor comprising first pixels and second pixels distinct from the first pixels, wherein the first pixels comprise a first electrode, an active layer, and a second electrode electrically coupled to a conductive track, the second pixels, comprising less than two electrodes and comprising at least no first electrode.

3. The image sensor according to claim 2, wherein each second pixel is formed of one or a plurality of elements selected, in a smaller number, among elements forming the first pixels.

4. The image sensor according to claim 2, wherein the second pixels comprise no active layer.

5. The image sensor according to claim 2, wherein, in the first pixels, the second electrode is coupled to the conductive track by a conductive via.

6. The image sensor according to claim 5, wherein, in the second pixels, the second electrode is not coupled to the conductive track by a conductive via.

7. The image sensor according to claim 2, wherein the first pixels and the second pixels are juxtaposed and organized in rows and in columns.

8. The image sensor according to claim 7, wherein the second pixels are organized in columns which are adjacent and located on one of the edges of the sensor or distributed on two edges of the sensor.

9. A method of manufacturing an image sensor according to claim 2, comprising the following steps:
forming the second electrode on a surface of a stack;
forming the active layer on the lower electrodes, on the side of said surface; and
forming the first electrode on the active layer, on the side of said surface,
to form the first pixels.

10. The method according to claim 9, further comprising a step of removal of all or part of the first electrode or of the first electrode and of the active layer, to form the second pixels.

11. The method according to claim 9, wherein the forming of the second pixels comprises only part of said steps, to obtain the sensor.
